(19) United States
(12) Patent Application Publication
(10) Pub. No.: US 2025/0016911 A1
(43) Pub. Date: Jan. 9, 2025

(54) METHODS, APPARATUSES, INTEGRATED CIRCUITS, AND PRINTED CIRCUIT BOARDS FOR POWER CONVERSION WITH REDUCED PARASITICS

(71) Applicant: Murata Manufacturing Co., Ltd., Nagaokakyo-shi (JP)

(72) Inventors: Gregory Szczeszynski, Nashua, NH (US); Tim Wen Hui Yu, Fremont, CA (US); John Weld, San Diego, CA (US)

(21) Appl. No.: 18/893,873

(22) Filed: Sep. 23, 2024

Related U.S. Application Data
(63) Continuation of application No. PCT/US2023/064783, filed on Mar. 21, 2023.
(60) Provisional application No. 63/321,930, filed on Mar. 21, 2022.

(51) Int. Cl. H05K 1/02; H02M 1/00; H02M 3/00; H02M 3/07; H02M 3/158; H05K 1/18

(52) U.S. Cl. CPC H05K 1/0262; H02M 1/0048; H02M 3/003; H02M 3/07; H02M 3/158; H05K 1/181; H05K 2201/0792; H05K 2201/1003

(57) ABSTRACT

An apparatus may include a printed circuit board including an integrated circuit including buck converter circuitry and an inductor coupled to the integrated circuit.

### CROSS-REFERENCE TO RELATED APPLICATIONS

This application is a continuation of International Patent Application No. PCT/US2023/064783 filed Mar. 21, 2023 and entitled “METHODS, APPARATUSES, INTEGRATED CIRCUITS, AND PRINTED CIRCUIT BOARDS FOR POWER CONVERSION WITH REDUCED PARASITICS,” which claims priority to and the benefit of U.S. Provisional Patent Application No. 63/321,930 filed Mar. 21, 2022 and entitled “METHODS, APPARATUSES, INTEGRATED CIRCUITS, AND PRINTED CIRCUIT BOARDS FOR POWER CONVERSION WITH REDUCED PARASITICS,” all of which are hereby incorporated by reference in their entirety.

### TECHNICAL FIELD

The present disclosure relates to power conversion, and more particularly, to methods, apparatuses, integrated circuits, and printed circuit boards for power conversion with reduced parasitic losses.

### BACKGROUND

Many electronic products, particularly mobile computing and/or communication products and components (e.g., notebook computers, ultra-book computers, tablet devices, LCD and LED displays), require multiple voltage levels. For example, power amplifiers for radio frequency transmitters may require relatively high voltages (e.g., 12 volts (V) or more), and logic circuitry may require a low voltage level (e.g., 1-2 V). Some other circuitry may require an intermediate voltage level (e.g., 5-10 V). Power converters are often used to generate a lower or higher voltage from a common power source, such as a battery, in order to meet the power requirements of different components in electronic products.

### SUMMARY

Embodiments of the present disclosure may provide methods, apparatuses, integrated circuits, and printed circuit boards for power conversion with reduced parasitic losses.

It is to be understood that the foregoing general description and the following detailed description are exemplary and explanatory only, and are not restrictive of the invention, as claimed.

### BRIEF DESCRIPTION OF THE DRAWINGS

FIG. 1 is a block diagram of an exemplary controller for power conversion, in accordance with embodiments of the present disclosure.

FIG. 2 is a circuit diagram of an exemplary controller with power switches, in accordance with embodiments of the present disclosure.

FIG. 3 is a perspective view of an exemplary apparatus for power conversion, in accordance with embodiments of the present disclosure.

FIG. 4 is a top view of an exemplary printed circuit board for power conversion, in accordance with embodiments of the present disclosure.

FIG. 5 is a top view of an exemplary printed circuit board for power conversion, in accordance with disclosed embodiments.

FIG. 6 is a diagram of electrical and optical signals of a printed circuit board layer.

FIG. 7A is a perspective view of an exemplary portion of an integrated circuit for power conversion, in accordance with embodiments of the present disclosure.

FIG. 7B is an expanded perspective view of the exemplary portion of the integrated circuit for power conversion of FIG. 7A, in accordance with embodiments of the present disclosure.

FIG. 7C is a side view of the exemplary portion of the integrated circuit for power conversion of FIGS. 7A and 7B, in accordance with embodiments of the present disclosure.

FIG. 8 is a sectional view of an exemplary integrated circuit for power conversion, in accordance with embodiments of the present disclosure.

FIG. 9 is a sectional view of an exemplary integrated circuit for power conversion, in accordance with embodiments of the present disclosure.

FIG. 10 is a top view of an exemplary portion of an integrated circuit for power conversion, in accordance with embodiments of the present disclosure.

FIG. 11 is a top view of an exemplary lead frame for power conversion, in accordance with embodiments of the present disclosure.

FIG. 12 is a bottom view of an exemplary lead frame for power conversion, in accordance with embodiments of the present disclosure.

FIG. 13 is a top view of exemplary transistors of a portion of an integrated circuit for power conversion, in accordance with embodiments of the present disclosure.

FIG. 14 is a top view of exemplary portions of transistors of FIG. 13, in accordance with embodiments of the present disclosure.

FIG. 15 is a top view of an exemplary redistribution layer of an integrated circuit, in accordance with embodiments of the present disclosure.

FIG. 16 is a top view of exemplary transistors of a portion of an integrated circuit for power conversion, in accordance with embodiments of the present disclosure.

FIG. 17 is a top view of an exemplary portion of transistors of FIG. 16, in accordance with embodiments of the present disclosure.

FIG. 18 is a top view of an exemplary portion of transistors of FIG. 16, in accordance with embodiments of the present disclosure.

FIG. 19 is a top view of an exemplary portion of transistors of FIG. 16, in accordance with embodiments of the present disclosure.

FIG. 20 is a top view of an exemplary portion of transistors of FIG. 16, in accordance with embodiments of the present disclosure.

FIG. 21 is a top view of an exemplary portion of transistors of FIG. 16, in accordance with embodiments of the present disclosure.

FIG. 22 is a top view of an exemplary portion of transistors of FIG. 21, in accordance with embodiments of the present disclosure.

FIG. 23 is a circuit diagram of an exemplary apparatus including an integrated circuit or controller for power conversion, in accordance with embodiments of the present disclosure.

### DETAILED DESCRIPTION

The following disclosure provides different exemplary embodiments, or examples, for implementing different features of the provided subject matter. Specific simplified examples of components and arrangements are described below to explain the present disclosure. These embodiments are examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Spatially relative terms, such as “beneath,” “below,” “lower,” “bottom,” “above,” “upper”, “top,” “toward,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled”, and the term “connected” may be termed as “electrically connected”. “Coupled” and “connected” may also be used to indicate that two or more elements cooperate or interact with each other.

Power converters can receive, deliver or operate with high current in one or more of the current paths. The power delivery path and operation at high current can be susceptible to parasitic losses that negatively impact performance. Parasitic losses may be described as the product of I² and R, where “I” is current and “R” is resistance. As the current increases, the power loss becomes more pronounced. For example, the power delivery path and the high current of certain buck converters can reduce their power conversion efficiency due to the parasitic losses. Additional constraints may further exacerbate unwanted parasitic losses. For example, die space may be limited, prompting signals to be fanned out on a printed circuit board (PCB) and be routed as needed.

For example, in some applications (e.g., servers, routers, etc.), optical cables may be interfaced using small form-factor pluggable (SFP) modules (e.g., optical transceivers, quad SFPs (QSFPs), octal SFPs (OSFPs), bidirectional QSFP28 (BIDI QSFP28), QSFP double density (QSFP-DD), applications where transmission rates are greater than 200 Gigabits per second (G), 400 G, greater than 200 G, etc.). These modules require high current (e.g., 20 ampere (A)) and low voltage (e.g., 0.5 volts (V)) outputs to operate at high performance. However, high current, low voltage paths are very sensitive to parasitic losses in a PCB. Moreover, SFP modules use narrow and long PCBs, which may further exacerbate unwanted parasitic losses in the PCB.

Typical SFP modules may suffer from parasitic losses. For example, typical SFP modules use a single integrated circuit coupled to one or more inductors to convert an input voltage (e.g., from 3.3 V to 0.5 V at 20 A) to an output voltage for a coupled main signal processing application-specific integrated circuit (ASIC). One or more terminals of the single integrated circuit is coupled to one or more inductors which is further coupled to the main signal processing ASIC. Typically, in order to increase current provided by the single integrated circuit and the one or more inductors to the ASIC, the terminals are placed on multiple sides of the integrated circuit. However, using multiple terminals in close proximity to transfer current to inductors from a single integrated circuit results in so-called “current crowding” along the current path. Current crowding may increase current density that causes increased parasitic losses in a PCB.

Disclosed embodiments may, among other things, reduce such parasitic losses by routing current from an input voltage to one or more integrated circuits, where each integrated circuit includes buck converter circuitry. For example, the one or more integrated circuits may be positioned adjacent to each other along a width of a PCB such that current crowding on each integrated circuit is reduced or eliminated. In some embodiments, each integrated circuit may be coupled to one or more inductors by corresponding terminals. For example, each terminal may be positioned on a same or common side of each integrated circuit such that each inductor of the one or more inductors are adjacent to each other on the same or common side of the one or more integrated circuits. Disclosed embodiments may reduce or eliminate current crowding on any of the one or more integrated circuits by routing current from the input voltage to the one or more terminals across a width of the PCB, thereby reducing or eliminating parasitic losses and increasing efficiency in the PCB.

Disclosed embodiments may include designs that reduce the inductor requirements for buck converters. For example, embodiments may include one or more charge pumps either part of each integrated circuit, or in separate integrated circuit(s), to reduce input voltage provided to each buck converter.

Because this arrangement reduces the inductor requirements for the buck converter (e.g., each inductor may have a dimension of 2.5 mm×2.0 mm×1.2 mm), it may permit embodiments to use chip inductors for the buck converter even with relatively high input voltage (e.g., 3.3 V). For example, each integrated circuit may be coupled to a corresponding charge pump such that each charge pump may step down the input voltage before it is provided to the corresponding buck converter. Allowing the buck converter to operate using a stepped-down voltage may reduce the demands on its associated inductor such that a chip inductor may be used instead of a larger inductor that takes up additional space.

While embodiments of the present disclosure may address these challenges and provide these benefits, the stated problems and features are intended to be examples and not limit the claims or scope of this disclosure. Indeed, the disclosed embodiments may address challenges and provide benefits not explicitly enumerated.

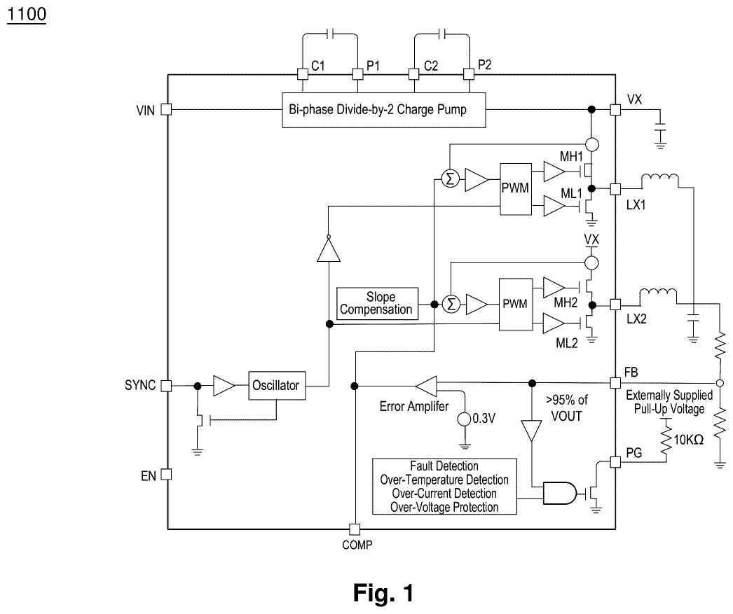

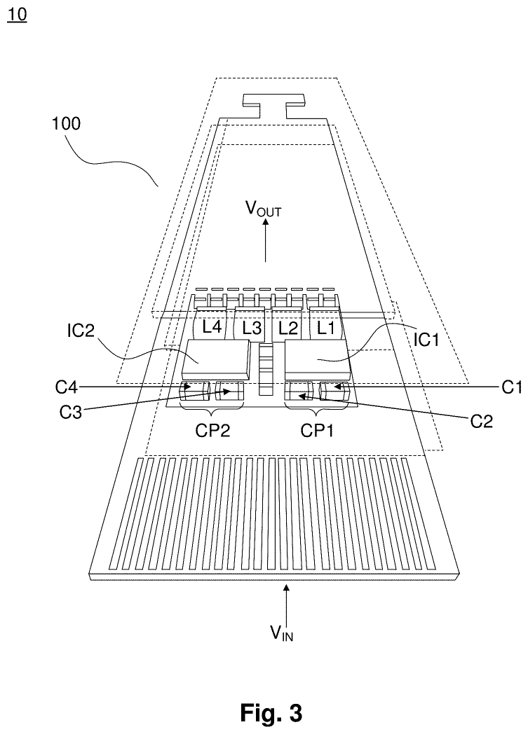

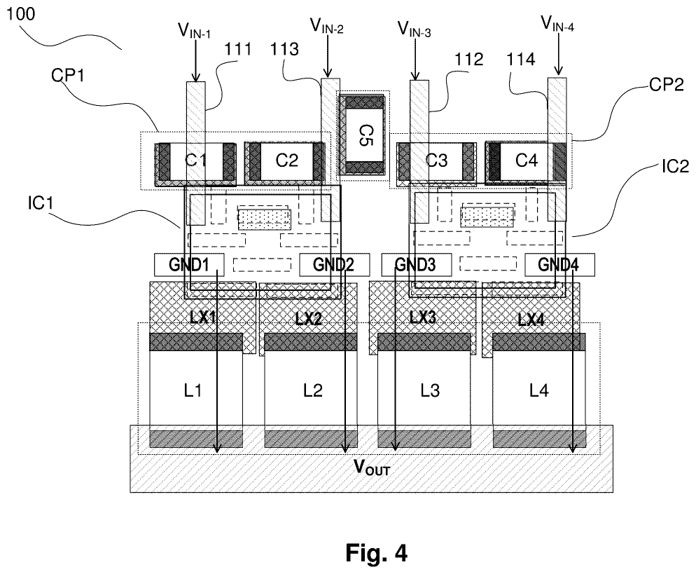

FIG. 1 is a block diagram 1100 of an exemplary integrated circuit or controller (e.g., integrated circuit IC1, integrated circuit IC2, integrated circuit IC_{N} of FIG. 3, FIG. 4, etc.) of a PCB (e.g., PCB 100 of FIG. 3, FIG. 4, etc.) for power conversion, in accordance with disclosed embodiments. As shown in FIG. 1, an integrated circuit or controller may provide a 2-phase charge pump with dual outputs represented by terminal LX1 and terminal LX2. It should be understood that when two integrated circuits are used, the two integrated circuits may use a total of four terminals (e.g., terminal LX1, terminal LX2, terminal LX3, and terminal LX4). The integrated circuit or controller may include an input voltage VIN and a charge pump with capacitors C1, C2, (e.g., flying capacitors). The integrated circuit or controller may include terminals VX, LX1, LX2, and PGND. The integrated circuit or controller may include a compensation terminal COMP, an enable input EN, a sync terminal SYNC, and a feedback terminal FB. PCB 100 may include transistors MH1, MH2, ML1, and ML2.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

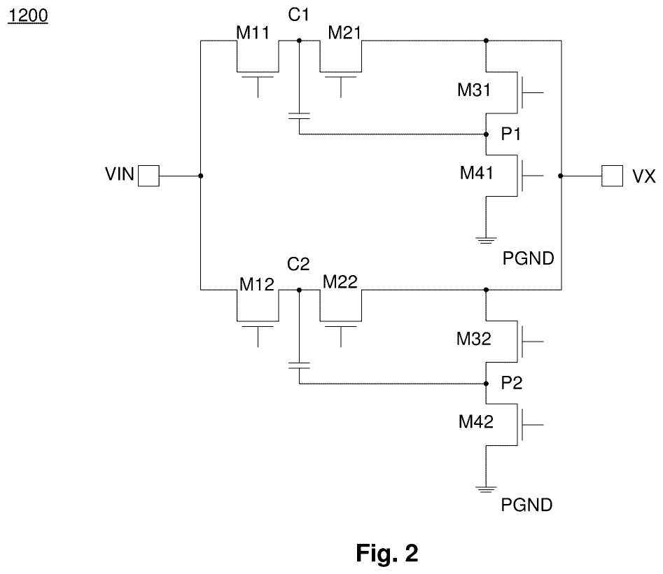

FIG. 2 is a circuit diagram 1200 of an exemplary apparatus including an integrated circuit or controller (e.g., integrated circuit IC1, integrated circuit IC2, integrated circuit IC_{N}) of a PCB (e.g., PCB 100) for power conversion, in accordance with disclosed embodiments. As shown in FIG. 2, an integrated circuit or controller may include an input voltage VIN and an output voltage VX. The integrated circuit or controller may include terminals PGND, C1, C2, P1, and P2. The integrated circuit or controller may include transistors M11, M21, M31, M41, M12, M22, M32, and M42.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

FIG. 3 is a perspective view of exemplary apparatus 10 (e.g., a SFP module) for power conversion, in accordance with disclosed embodiments. FIG. 4 is a top view of exemplary PCB 100 for power conversion, in accordance with disclosed embodiments. As shown in FIG. 3, apparatus 10 may include PCB 100. As shown in FIG. 3 and FIG. 4, PCB 100 may include charge pump CP1, charge pump CP2, integrated circuit IC1, integrated circuit IC2, inductor L1, inductor L2, inductor L3, and inductor L4. Charge pump CP1 may include capacitor C1 and capacitor C2. Charge pump CP2 may include capacitor C3 and capacitor C4. Integrated circuit IC1 and integrated circuit IC2 may each include buck converter circuitry for power conversion. In some embodiments, PCB 100 may include a capacitor C5. In some embodiments, capacitors (e.g., capacitors C1, C2, C3, C4, or C5) may be 22 microfarad (μF) capacitors.

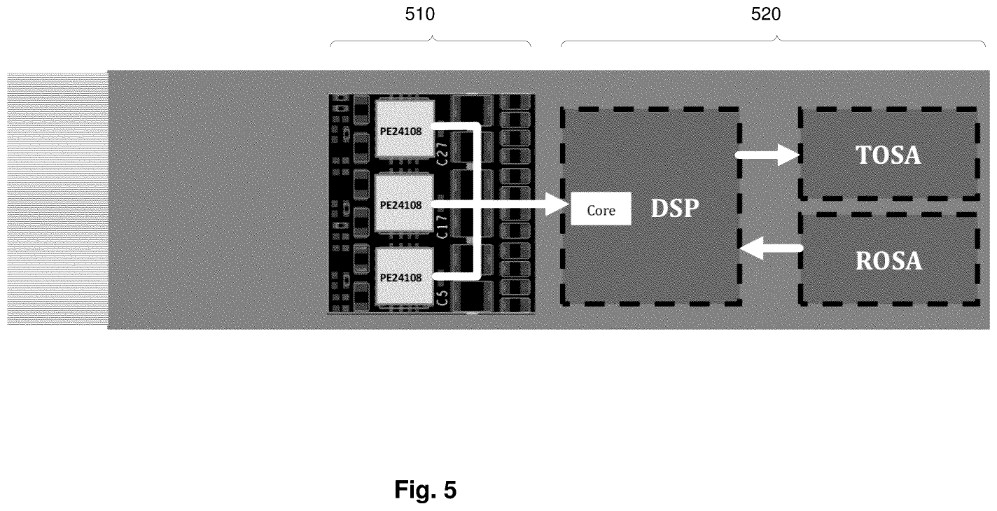

FIG. 5 is a top view of an exemplary PCB for power conversion, in accordance with disclosed embodiments. In some embodiments, the power converter may be placed underneath the ASIC. In some embodiments, the PCB may have a dual-PCB layer as shown by the dotted line in FIG. 5. For example, the PCB may have a first PCB layer 510 and a second PCB layer 520, where second PCB layer 520 may include a digital signal processor (DSP) component, a transoptical subassembly (TOSA), and a receiver optical subassembly (ROSA). The dual-PCB allows for designs with taller inductors that may not conform to a single PCB layer with smaller inductor. The application may benefit from the embodiments as described previously and embodiments described further below.

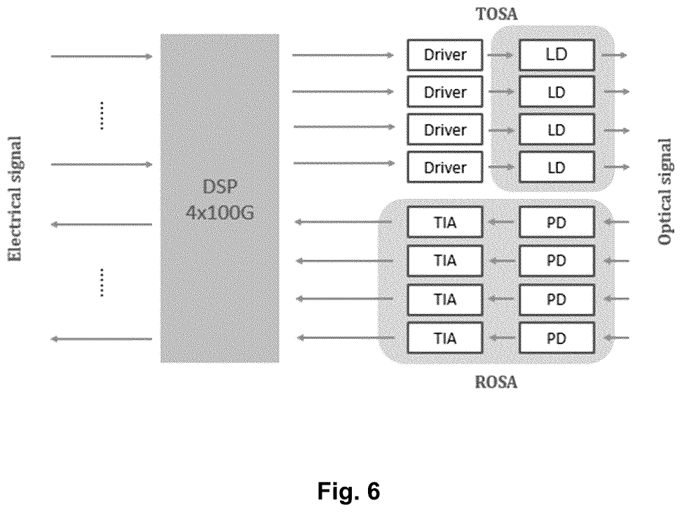

FIG. 6 is a diagram of electrical and optical signals of second PCB layer 520. The TOSA may include one or more drivers and one or more laser diodes LDs. The ROSA may include one or more transimpedance amplifiers TIA and one or more photodiodes PDs.

As shown in FIG. 4, integrated circuit IC1 may be coupled to inductor L1 by terminal LX1 and coupled to inductor L2 by terminal LX2. Similarly, integrated circuit IC2 may be coupled to inductor L3 by terminal LX3 and coupled to inductor L4 by terminal LX4. In some embodiments, an inductor (e.g., inductors L1, L2, L3, or L4) may include, on one side of the inductor, a pin to which a chip inductor connects. The other side of the inductor may connect to a pin (e.g., a VX pin) or a ground pin (e.g., terminals GND1, GND2, GND3, or GND4) via power switches. In some embodiments, integrated circuit IC1 and inductor L1 may convert an input voltage V_{IN-1} to output voltage V_{OUT} and integrated circuit IC1 and inductor L2 may convert an input voltage V_{IN-2} to output voltage V_{OUT}. Similarly, integrated circuit IC2 and inductor L3 may convert an input voltage V_{IN-3} to output voltage V_{OUT} and integrated circuit IC2 and inductor L4 may convert an input voltage V_{IN-4} to output voltage V_{OUT}. In one example, V_{IN-1} to V_{IN-4} may receive an input voltage supplied from a common source. In another example, V_{IN-1} to V_{IN-4} may receive an input voltage supplied from multiple sources.

In some embodiments, the layout of PCB 100 may be designed to reduce or eliminate parasitic losses along certain conductive paths of PCB 100. For example, the field effect transistor (FET) formed with the terminals between a buck converter and an inductor may be particularly susceptible to the parasitic losses caused by current crowding on the integrated circuit of the buck converter. Disclosed embodiments may, among other things, reduce such unwanted parasitic losses by routing current from an input voltage to integrated circuit IC1 and to integrated circuit IC2. Integrated circuits IC1 and IC2 may be positioned adjacent to each other along a width of PCB 100 such that current crowding on integrated circuits IC1 and IC2 in reduced or eliminated.

Disclosed embodiments may advantageously reduce parasitic losses by optimizing a critical path of the integrated circuit (IC) at the cost of a non-critical path. A buck converter operating at a low duty cycle (e.g., <50%) is more dependent on the low-side FET current path (e.g., ML1) for better efficiency than the high-side current path (e.g., MH1). For example, disclosed embodiments may optimize the critical path GND-ML1-LX of an integrated circuit (e.g., integrated circuits IC1, IC2, or IC_{N}) from a switch to a terminal (e.g., terminals LX1, LX2, LX3, or LX4) on one side of the integrated circuit at the cost of the non-critical path LX-MH1-VX at another side of the integrated circuit from a switch to a charge pump (e.g., charge pumps CP1 or CP2). Disclosed embodiments may reduce parasitic losses by using a lead frame to bridge the distance between the critical path and the non-critical path. For example, the charge pump and the integrated circuit may use the lead frame.

As shown in FIG. 3 and FIG. 4, terminals GND1, GND2, GND3, and GND4 may be positioned on a same or common side of integrated circuits IC1 and IC2 such that inductors L1, L2, L3, and L4 are adjacent to each other on the same or common side of integrated circuits IC1 and IC2. Disclosed embodiments may reduce or eliminate current crowding on integrated circuits IC1 and IC2 by routing current from the input voltage to terminals GND1, GND2, GND3, and GND4 across a width of PCB 100, thereby reducing or eliminating parasitic losses and increasing power conversion efficiency in PCB 100. That is, since terminals GND1, GND2, GND3, and GND4 are positioned across a width of PCB 100, current that is transferred from the input voltage to each inductor of inductors L1, L2, L3, and L4 is a low density current, resulting in low resistive losses in PCB 100. Because terminals GND1, GND2, GND3, GND4, LX1, LX2, LX3, and LX4 are positioned adjacent to each other across the width of PCB 100, current from the input voltage may advantageously be maximized and prevented from crowding onto any one of inductors L1, L2, L3, or L4.

Inductors L1, L2, L3, and L4 may be chip inductors that may feature a small package and may be used for various applications, including power conversion and high-frequency circuitry. A chip inductor may be an inductor that comes in the form factor of a chip for use in an integrated circuit of an electronic device. Chip inductors may be used in power converters, RF transceivers, computers, and other electronic devices. An example chip inductor may include a ferrite core with a wire winding or may have multiple layers of wires. Chip inductors may offer the benefits of conserving voltage and may be used to form filter circuits and resonant circuits. As compared with conventional discrete inductors, chip inductors may be more compact and may weigh less.

While, FIG. 3 and FIG. 4 illustrate two integrated circuits and four inductors, it should be understood that embodiments of this disclosure are not limited to such a configuration. For example, combinations of any number of integrated circuits (e.g., one or more integrated circuits) and any number of inductors (e.g., one or more inductors) may be used in the present disclosure.

As shown in FIG. 3 and FIG. 4, PCB 100 may include charge pump CP1 to step down input voltages V_{IN-1} and V_{IN-2}, where charge pump CP1 may be a dual phase charge pump formed by integrated circuit IC1 in conjunction with capacitors C1 and C2, where each phase is divided by two. Integrated circuit IC1 may include power switches that are coupled to capacitors C1 and C2. For example, charge pump CP1 may form a divided-by-two dual phase charge pump. Similarly, integrated circuit IC2 may include power switches that are coupled to capacitors C3 and C4, and charge pump CP2 may form a divided-by-two dual phase charge pump.

Charge pump CP1 may be arranged between input voltages V_{IN-1} and V_{IN-2} and integrated circuit IC1. Similarly, PCB 100 may include charge pump CP2 to step down input voltages V_{IN-3} and V_{IN-4}, where charge pump CP2 may be a dual phase charge pump formed by integrated circuit IC2 in conjunction with capacitors C3 and C4, where each phase is divided by two. Charge pump CP2 may be arranged between input voltages V_{IN-3} and V_{IN-4} and integrated circuit IC2.

Integrated circuit IC1 in conjunction with inductors L1 and L2 may form a first buck regulator. Similarly, integrated circuit IC2 in conjunction with inductors L3 and L4 may form a second buck regulator. Integrated circuit IC1 and integrated circuit IC2 may include power switches for the first and second buck regulators, respectively.

Charge pump CP1 may step down input voltages V_{IN-1} and V_{IN-2} before they are provided to integrated circuit IC1. Similarly, charge pump CP2 may step down input voltages V_{IN-3} and V_{IN-4} before they are provided to integrated circuit IC2. A lower input voltage to the buck converter may reduce the demands on inductors L1, L2, L3, and L4. In some embodiments, inductors L1, L2, L3, and L4 may therefore be implemented by chip inductors instead of larger inductors that take up additional space.

In some embodiments, current may be transferred to terminals (e.g., terminals GND1 or GND2) on an integrated circuit (e.g., integrated circuit IC1) from a corresponding charge pump (e.g., charge pump CP1) non-simultaneously. For example, current may transfer from charge pump CP1 to terminal GND1 at a point in time without any current transferring from charge pump CP1 to terminal GND2. This operation may further reduce or eliminate negative parasitic losses from current crowding on any terminals or inductors, thereby increasing power conversion efficiency. This non-simultaneous current transfer may similarly occur with terminals GND2, GND3, or GND4.

While the integrated circuits (e.g., integrated circuits IC1, IC2, or IC_{N}) include power switches that connect to capacitors and inductors to form charge pumps and buck regulators that offer some advantages and are depicted in FIG. 3 and FIG. 4, it should be understood that the present disclosure could include layouts of PCB 100 without any charge pumps. Embodiments described herein without charge pumps may reduce or eliminate parasitic losses in PCB 100. Furthermore, while FIG. 3 and FIG. 4 depict two charge pumps, it should be understood that the present disclosure does not limit the embodiments to two charge pumps and any number of charge pumps may be used (e.g., one or more charge pumps). The one or more charge pumps can operate as single phase, dual phase, or N-phase. In other examples, any number of regulators may be used (e.g., one or more buck regulators, Cuk converter, multi-level, etc). The one or more regulators can operate as single phase, dual phase, or N-phase.

During power conversion, currents may flow from charge pump C1 to integrated circuit IC1 through conductive lines 111 and 113 and currents may flow from charge pump C2 to integrated circuit IC2 through conductive lines 112 and 114. While other conductive lines and terminals are depicted, but not labelled, in FIG. 4, it should be understood that they operate in a manner similar to conductive lines 111, 112, 113, and 114 and terminals GND1, GND2, GND3, GND4, LX1, LX2, LX3, and LX4.

While disclosed embodiments have described power conversion in the direction from the charge pump to the buck converter, it should be understood that disclosed embodiments are applicable to power conversion in the opposite direction as well (e.g., from the buck converter to the charge pump, wherein a buck converter run backwards is referred to as a boost converter).

While disclosed embodiments have been described with respect to SFP modules, it should be understood that disclosed embodiments are applicable to other applications as well, such as, e.g., any high current, low output voltage applications where the total available width or area of a PCB is limited (though the disclosed embodiments are not limited to such applications).

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

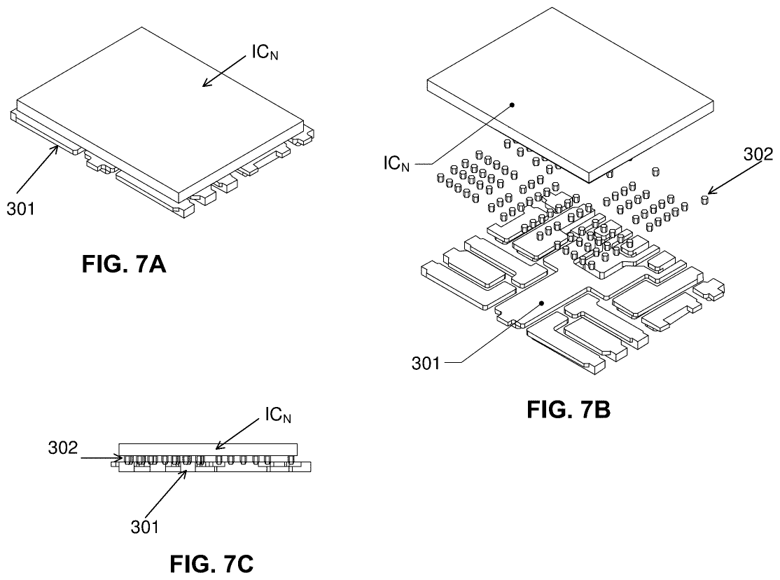

FIG. 7A is a perspective view of a portion of an IC (e.g., a portion of IC), FIG. 7B is an expanded perspective view of the portion of the IC, and FIG. 7C is a side view of the portion of the IC, in accordance with disclosed embodiments. As shown in FIGS. 7A, 7B, and 7C, an integrated circuit IC_{N} (e.g., integrated circuits IC1 or IC2 of FIG. 3 or FIG. 4) may be attached to a lead frame 301 by pillars 302 (e.g., copper pillars).

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

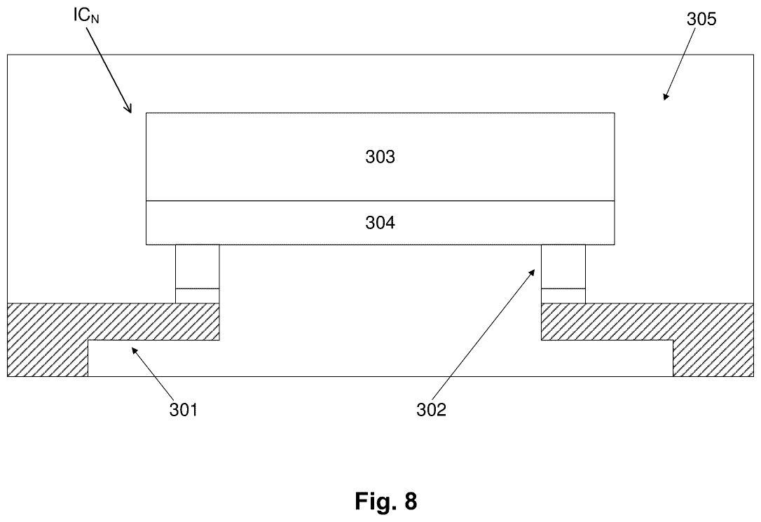

FIG. 8 is a sectional view of a portion of an IC (e.g., a portion of IC, the portion of the IC FIGS. 7A, 7B, and 7C, etc.), in accordance with disclosed embodiments. As shown in FIG. 8, integrated circuit IC_{N} (e.g., integrated circuits IC1 or IC2 of FIG. 3 or FIG. 4, integrated circuit IC_{N} of FIGS. 7A, 7B, 7C, etc.) may include a die 303 (e.g., a silicon die) and interconnect 304. Integrated circuit IC_{N} may be attached to lead frame 301 (e.g., lead frame 301 of FIGS. 7A, 7B, and 7C, etc.) by pillars 302 (e.g., pillars 302 of FIGS. 7A, 7B, and 7C, etc.). Integrated circuit IC_{N}, lead frame 301, and pillars 302 may be encapsulated by a material (e.g., molding material, insulating material, etc.). Lead frame 301 may comprise a thick metal (e.g., 150 micrometres of copper) that improves the routing of current from the input voltage, thereby reducing current crowding and reducing or eliminating unwanted parasitic losses in PCB 100.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

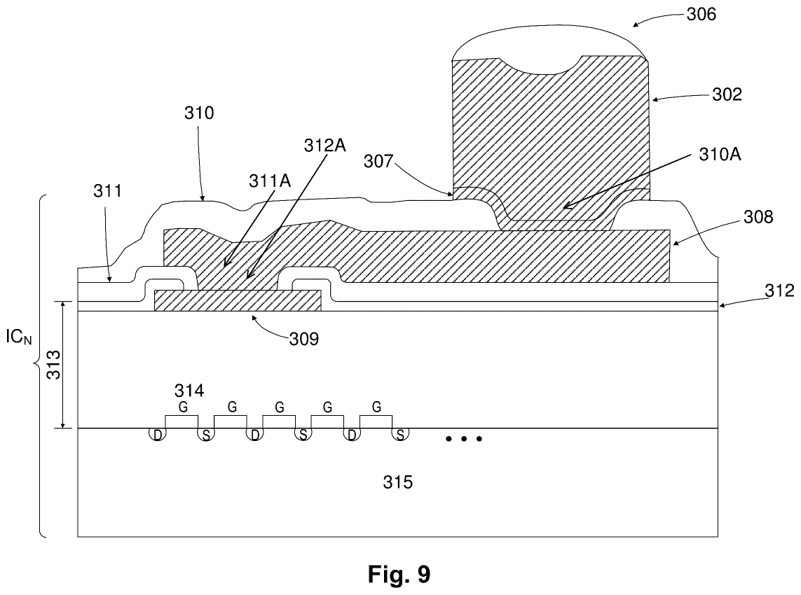

FIG. 9 is a sectional view of a portion of an integrated circuit (IC) (e.g., a portion of IC, the portion of the IC in FIGS. 7A, 7B, 7C, and 8, etc.), in accordance with disclosed embodiments. As shown in FIG. 9, the portion of the PCB includes integrated circuit IC_{N} (e.g., integrated circuits IC1 or IC2 of FIG. 3 or FIG. 4, integrated circuit IC_{N} of FIGS. 7A, 7B, 7C, 8, etc.) and pillar 302 (e.g., pillars 302 of FIGS. 7A, 7B, 7C, and 8, etc.). The IC may include a solder 306 on a first end of pillar 302 to join pillar 302 to lead frame 301 (e.g., lead frame 301 of FIGS. 7A, 7B, 7C, 8, etc.). The IC may include an under bump metallization (UBM) 307 on a second end of pillar 302, opposite to the first end, to connect pillar 302 (and lead frame 301) to integrated circuit IC_{N}.

As shown in FIG. 9, integrated circuit IC_{N} may include a redistribution layer (RDL) 308 (e.g., copper metal interconnect) and a metal layer 309 to connect or couple various components of the PCB. Integrated circuit IC_{N} may include an insulating layer 310 (e.g., polyimide) between UBM 307 and RDL 308, an insulating layer 311 (e.g., polyimide) between RDL 308 and an insulating layer 312 (e.g., Si₃N₄), where insulating layer 312 may be between insulating layer 311 and metal layer 309. Insulating layer 310 may include an opening 310A around or near pillar 302 and UBM 307, insulating layer 311 may include an opening 311A around or near RDL 308 and metal layer 309, and insulating layer 312 may include an opening 312A around or near metal layer 309. Integrated circuit IC_{N} may include a back end of line (BEOL) layer 313 including one or more devices 314 and a substrate 315 (e.g., silicon substrate).

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

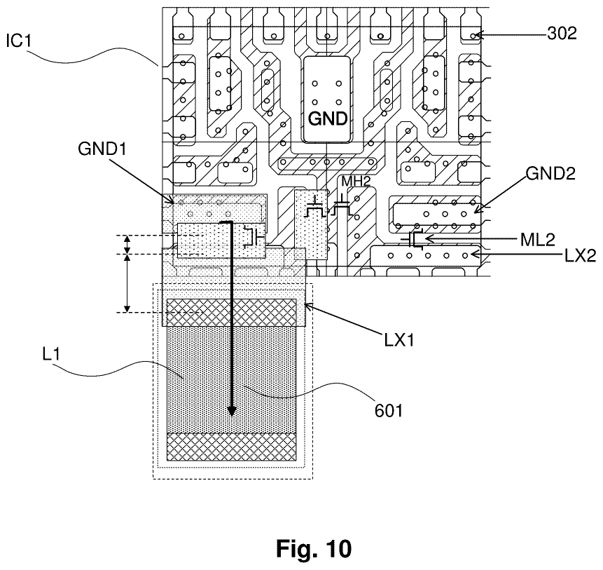

FIG. 10 is a top view of a portion of an IC (e.g., a portion of IC, the portion of the IC in FIGS. 7A, 7B, 7C, 8, and 9, etc.), in accordance with disclosed embodiments. As shown in FIG. 10, the portion of the PCB may include integrated circuit IC1, inductor L1, and terminals GND1, GND2, GND, LX1, and LX2. As described above, current flow 601 is shown in a direction from integrated circuit IC1 to inductor L1. FIG. 10 shows field effect transistors (FETs) formed in the PCB, including transistor MH2 and transistor ML2. Disclosed embodiments include transistors being formed using terminal GND1 and terminal LX1. In some embodiments, for the application of this converter (optical transceiver) the PCB may have a resistance of 0.4 milliOhms (mOhms), the lead frame may have a resistance of 0.4 mOhms, transistors may have a resistance of 1.5 mOhms or 2.1 mOhms, and a die metal may have a resistance of 1.5 mOhms, though other resistances are possible as well.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

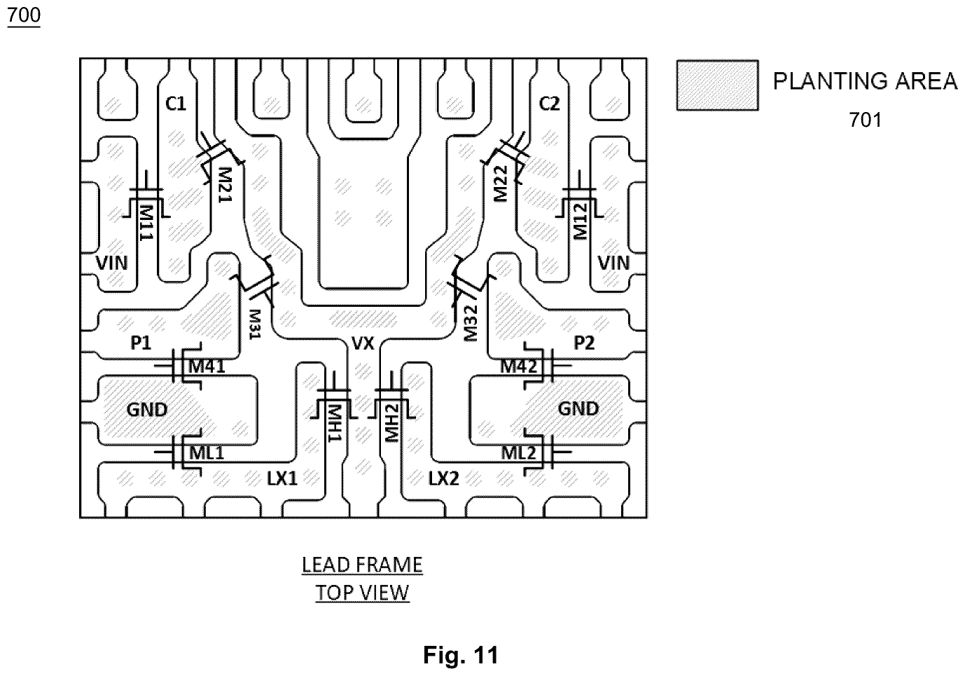

FIG. 11 is a top view 700 of lead frame 301 (e.g., lead frame 301 of FIGS. 7A, 7B, 7C, 8, 9, etc.), in accordance with disclosed embodiments. As shown in FIG. 11, lead frame 301 includes plating areas 701. Top view 700 of lead frame 301 shows for connecting the IC to terminals C1, C2, and VX, input voltage VIN, and terminals GND, LX1, LX2, P1, and P2. Top view 700 of lead frame 301 shows transistors M11, M12, M21, M22, M31, M32, M41, M42, MH1, MH2, ML1, and ML2. Lead frame 301 may comprise a thick metal (e.g., 150 micrometres of copper) that improves the routing of current from the input voltage, thereby reducing current crowding and reducing or eliminating unwanted parasitic losses in PCB 100.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

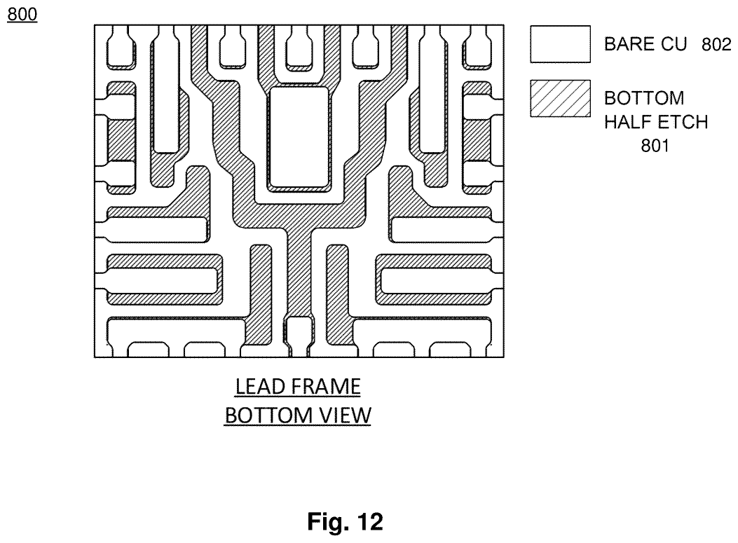

FIG. 12 is a bottom view 800 of lead frame 301 (e.g., lead frame 301 of FIGS. 7A, 7B, 7C, 8, 9, 11, etc.), in accordance with disclosed embodiments. As shown in FIG. 12, lead frame 301 includes bottom half etch areas 801 and bare copper areas 802.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

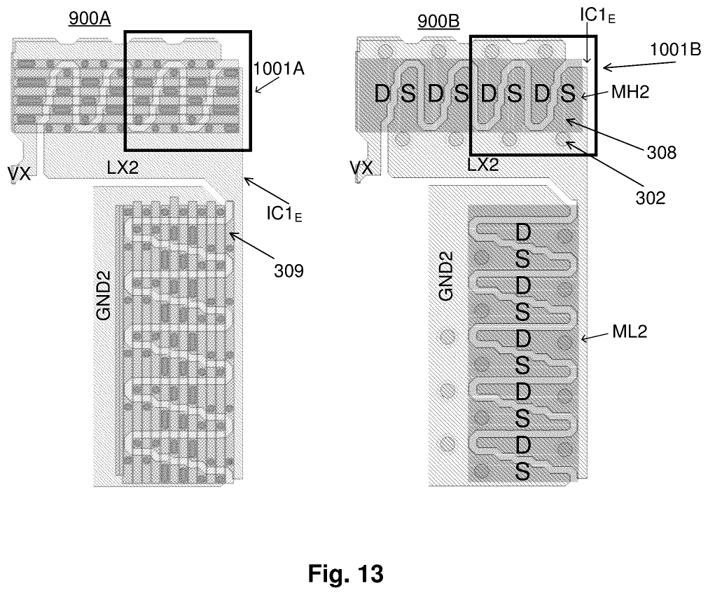

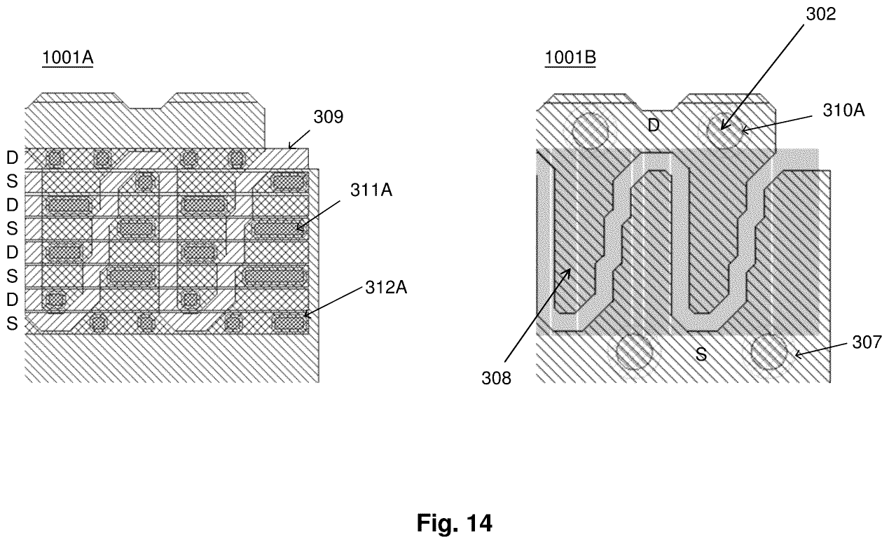

FIG. 13 is a top view of transistors MH2 and ML2 of a portion of an IC (e.g., a portion of IC, the portion of the IC in FIGS. 7A, 7B, 7C, 8, 9, and 10, etc.), in accordance with disclosed embodiments. FIG. 13 includes a first view 900A of transistors MH2 and ML2 and a second view 900B of transistors MH2 and ML2. First view 900A shows an edge IC1_{E} of integrated circuit IC1, metal layer 309, intermediate VX node, and terminals LX2, and GND2. Second view 900B shows edge IC1_{E} of integrated circuit IC1, pillar 302, RDL 308, sources S, drains D, intermediate VX node, and terminals LX2, and GND2. First view 900A and second view 900B include portions 1001A and 1001B, respectively, which are shown in FIG. 14.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

FIG. 14 is a top view of portions 1001A and 1001B of transistors MH2 and ML2, in accordance with disclosed embodiments. Portion 1001A shows metal layer 309, opening 311A of insulating layer 311, opening 312A of insulating layer 312A, sources S, and drains D. Portion 1001B shows opening 310A of insulating layer 310, RDL 308, UBM 307, pillar 302, source S, and drain D.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

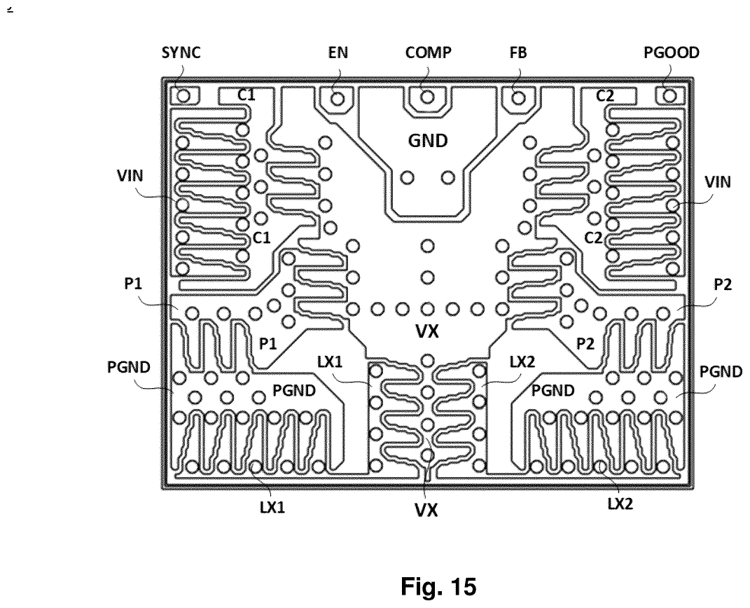

FIG. 15 is a top view 1500 of a RDL (e.g., RDL 308) of an integrated circuit (e.g., integrated circuits IC1, IC2, IC_{N}), in accordance with disclosed embodiments. As shown in FIG. 15, top view 1500 of the RDL shows for connecting an integrated circuit to terminals C1, C2, and VX, input voltage VIN, and terminals PGND, LX1, LX2, P1, and P2. Top view 1500 of the RDL shows a compensation pin COMP, an enable input EN, a sync pin SYNC, a feedback pin FB, and a power good pin PGOOD. In some embodiments, terminals PGND and GND are synonymous.

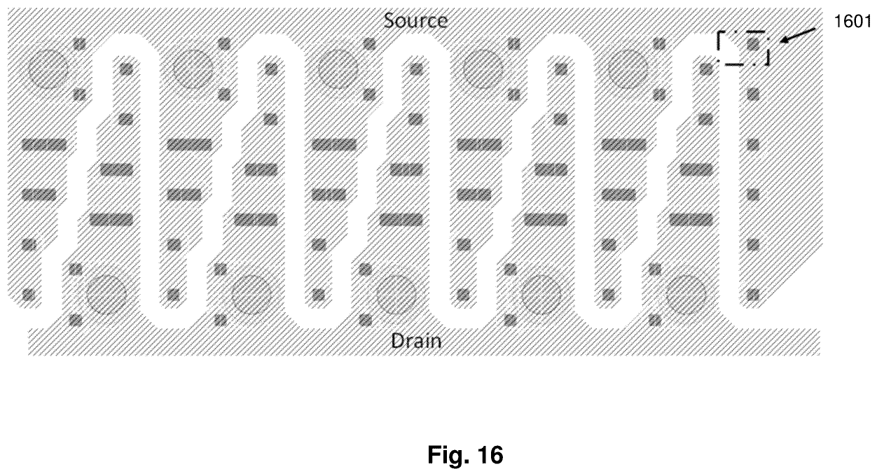

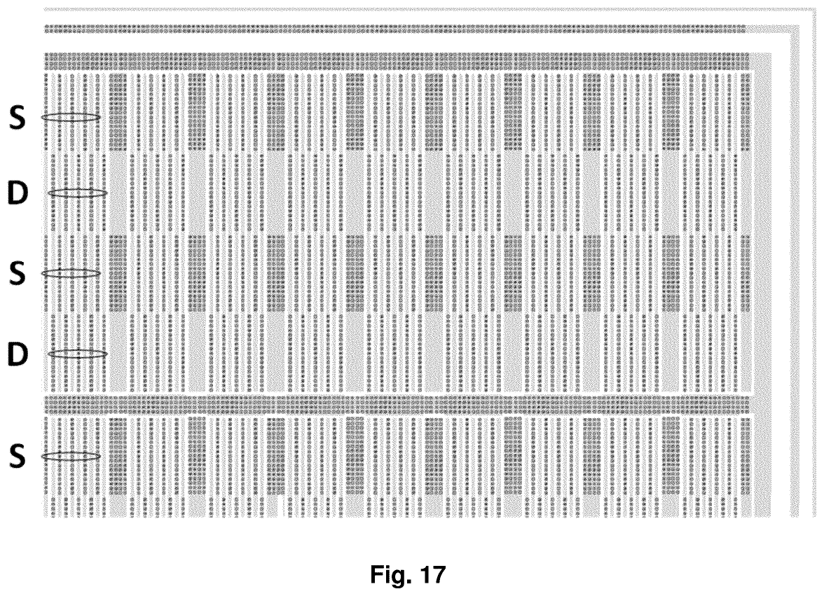

FIG. 16 is a top view of transistor ML2 of a portion of a IC (e.g., a portion of IC IC, the portion of the PCB in FIGS. 7A, 7B, 7C, 8, 9, and 10, etc.), in accordance with disclosed embodiments. FIG. 16 shows a source side, a drain side, and portion 1601, which is shown in FIGS. 17, 18, 19, 20, and 21.

FIG. 17 is a top view of portion 1601 of transistor ML2, in accordance with disclosed embodiments. Portion 1601 shows a first metal layer, vias between the first metal layer and a second metal layer, sources S, and drains D.

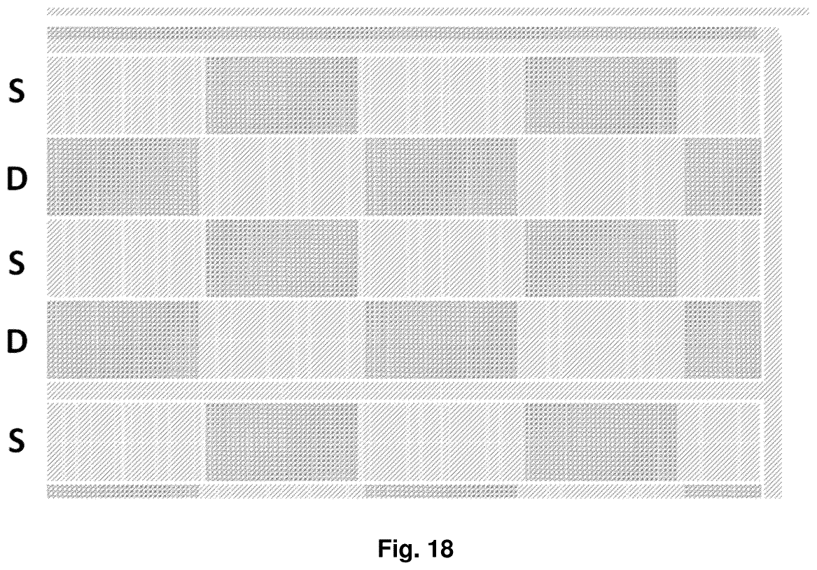

FIG. 18 is a top view of portion 1601 of transistor ML2, in accordance with disclosed embodiments. Portion 1601 shows a second metal layer, vias between the second metal layer and a third metal layer, sources S, and drains D.

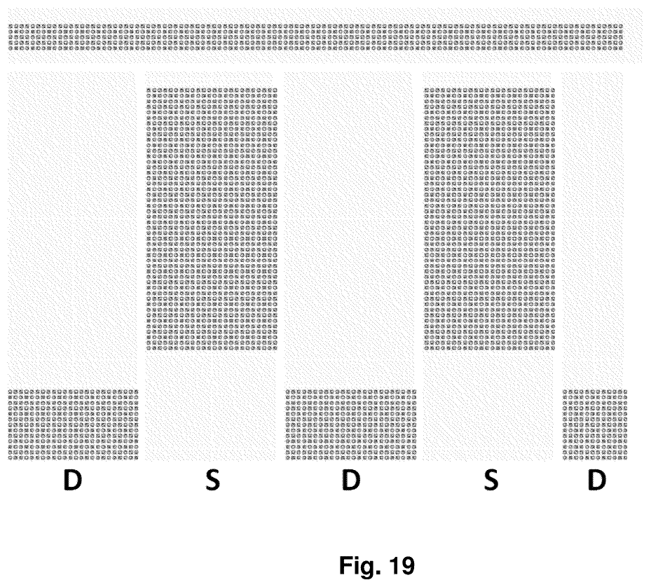

FIG. 19 is a top view of portion 1601 of transistor ML2, in accordance with disclosed embodiments. Portion 1601 shows a third metal layer, vias between the third metal layer and a fourth metal layer, sources S, and drains D.

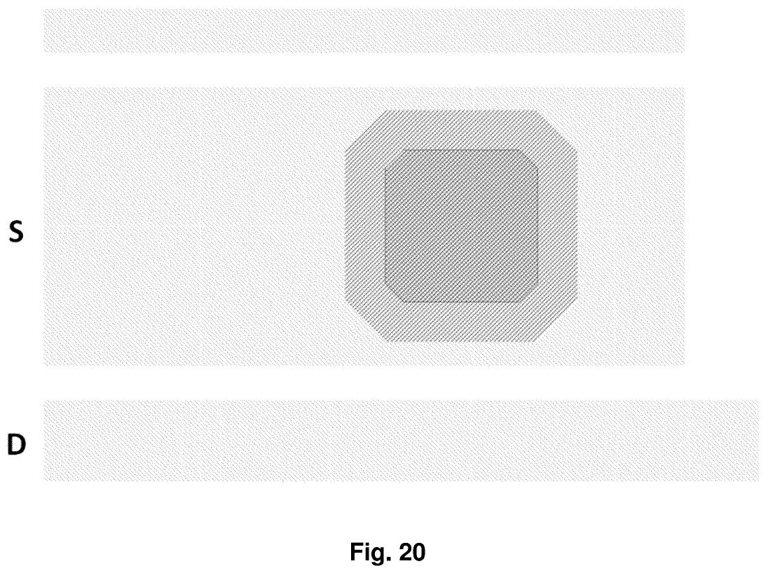

FIG. 20 is a top view of portion 1601 of transistor ML2, in accordance with disclosed embodiments. Portion 1601 shows a top metal layer (e.g., metal layer 309), insulating layers (e.g., insulating layers 310, 311, and/or 312), openings (e.g., openings 310A, 311A, and/or 312A), source S, and drain D.

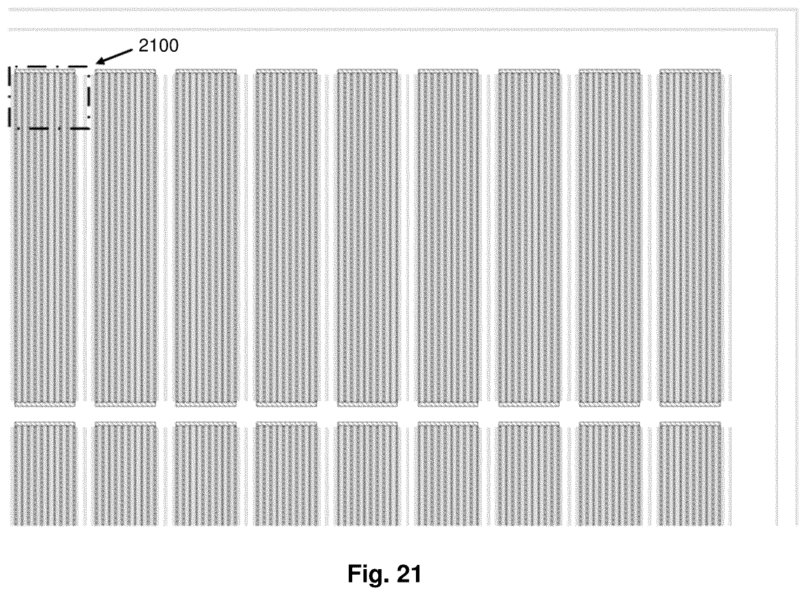

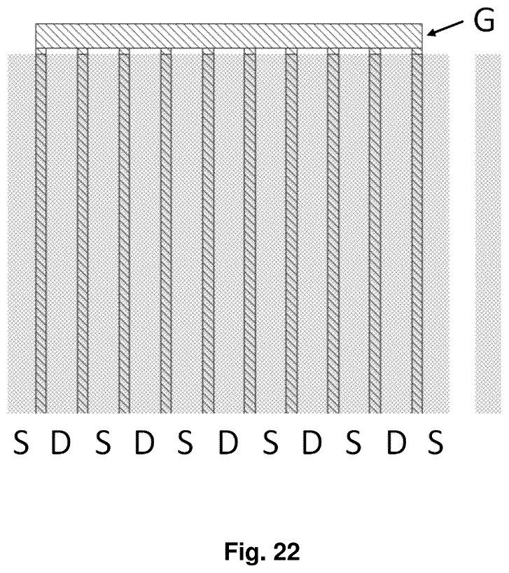

FIG. 21 is a top view of portion 1601 of transistor ML2, in accordance with disclosed embodiments. Portion 1601 shows polysilicon layers, diffusion layers, and portion 2100, which is shown in FIG. 22.

FIG. 22 is a top view of portion 2100 of transistor ML2, in accordance with disclosed embodiments. Portion 2100 shows a gate G, sources S, and drains D.

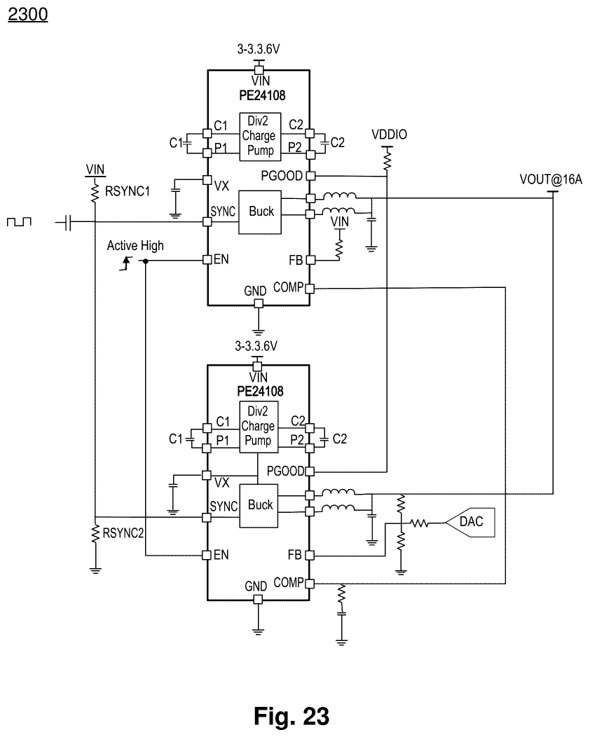

FIG. 23 is a circuit diagram 2300 of an exemplary apparatus including an integrated circuit or controller (integrated circuits IC1, IC2, IC_{N}) of a PCB (PCB 100) for power conversion, in accordance with disclosed embodiments. As shown in FIG. 23, an integrated circuit or controller may include an input voltage VIN and a charge pump with charge capacitors C1, C2, P1, and P2 (e.g., flying capacitors). The integrated circuit or controller may include terminals VX, GND and PGND. The integrated circuit or controller may include a compensation terminal COMP, an enable input EN, a sync terminal SYNC, a feedback terminal FB, and a power good pin PGOOD. The integrated circuit or controller may include transistors MH1, MH2, ML1, and ML2. PCB 100 may include buck converter Buck and output voltage VOUT.

It should be understood that in some embodiments, repeat reference numerals and/or letters in various figures of the present disclosure relate to one another and indicate that the figures relate to one another. In some other embodiments, this repetition does not in itself dictate a relationship between the various embodiments and/or configurations discussed.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is also intended that the sequence of steps shown in figures are only for illustrative purposes and are not intended to be limited to any particular sequence of steps. As such, those skilled in the art can appreciate that these steps can be performed in a different order while implementing the same method.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiments of the specification. Certain features described in the context of various embodiments are not to be considered essential features of those embodiments unless the embodiment is inoperative without those elements.

The embodiments may further be described using the following clauses:

1. A printed circuit board (PCB) for power conversion, the PCB comprising:
an integrated circuit comprising buck converter circuitry; and
an inductor coupled to the integrated circuit.

2. A printed circuit board (PCB) for power conversion, the PCB comprising:
a plurality of integrated circuits, wherein each integrated circuit of the plurality of integrated circuits comprises buck converter circuitry; and
a plurality of inductors coupled to each integrated circuit of the plurality of integrated circuits.

3. The PCB of clause 2, wherein each integrated circuit of the plurality of integrated circuits is coupled to each inductor of the plurality of inductors by a corresponding terminal.

4. The PCB of clause 3, wherein each corresponding terminal is positioned on a common side of each integrated circuit of the plurality of integrated circuits.

5. The PCB of clause 2, wherein the plurality of integrated circuits are adjacent to each other.

6. The PCB of clause 2, wherein the plurality of inductors are adjacent to each other on a common side of the plurality of integrated circuits.

7. The PCB of clause 2, wherein each integrated circuit of the plurality of integrated circuits is coupled to a corresponding charge pump.

8. The PCB of clause 7, wherein each corresponding charge pump comprises one or more capacitors.

9. An apparatus comprising the PCB of any one of clauses 1-8.

10. A printed circuit board (PCB) for power conversion comprising:
a first integrated circuit and a second integrated circuit, wherein the first integrated circuit and the second integrated circuit each comprises buck converter circuitry and the first integrated circuit and the second integrated circuit are positioned adjacent to each other;
a first inductor and a second inductor coupled to the first integrated circuit; and
a third inductor and a fourth inductor coupled to the second integrated circuit.

11. The PCB of clause 10, wherein:
the first integrated circuit is coupled to the first inductor by a first corresponding terminal and the first integrated circuit is coupled to the second inductor by a second corresponding terminal; and
the second integrated circuit is coupled to the third inductor by a third corresponding terminal and the second integrated circuit is coupled to the fourth inductor by a fourth corresponding terminal.

12. The PCB of clause 11, wherein each the first terminal, the second terminal, the third terminal, and the fourth terminal are positioned on a common side of each integrated circuit of the plurality of integrated circuits.

13. The PCB of clause 10, wherein the first inductor, the second inductor, the third inductor, and the fourth inductor are adjacent to each other on a common side of the first integrated circuit and the second integrated circuit.

14. The PCB of clause 10, wherein the first integrated circuit is coupled to a first charge pump and the second integrated circuit is coupled to a second charge pump.

15. The PCB of clause 14, wherein the first charge pump and the second charge pump each comprises one or more capacitors.

16. An apparatus comprising the PCB of any one of clauses 10-15.

1. A printed circuit board (PCB) for power conversion, the PCB comprising:
a plurality of integrated circuits, wherein each integrated circuit of the plurality of integrated circuits comprises buck converter circuitry; and
a plurality of inductors, wherein each inductor of the plurality of inductors is coupled to a respective integrated circuit of the plurality of integrated circuits.

2. The PCB of claim 1, wherein each integrated circuit of the plurality of integrated circuits is coupled to a respective inductor of the plurality of inductors by a corresponding terminal.

3. The PCB of claim 2, wherein each corresponding terminal is positioned on a common side of each integrated circuit of the plurality of integrated circuits.

4. The PCB of claim 2, further comprising a plurality of ground terminals adjacent to each other on a common side of the plurality of integrated circuits, wherein the plurality of ground terminals are further adjacent to the plurality of inductors.

5. The PCB of claim 4, wherein the PCB is configured to receive an input voltage routed to the plurality of ground terminals and further routed to the respective corresponding terminals and the plurality of inductors across a width of the PCB.

6. The PCB of claim 1, wherein the plurality of inductors are adjacent to each other on a common side of the plurality of integrated circuits.

7. The PCB of claim 1, wherein the plurality of integrated circuits are adjacent to each other.

8. The PCB of claim 1, wherein each integrated circuit of the plurality of integrated circuits is coupled to a corresponding charge pump.

9. The PCB of claim 8, wherein each corresponding charge pump comprises one or more capacitors.

10. A printed circuit board (PCB) for power conversion, the PCB comprising:
a plurality of integrated circuits comprising a first integrated circuit and a second integrated circuit, wherein the first integrated circuit and the second integrated circuit each comprises buck converter circuitry, and wherein the first integrated circuit and the second integrated circuit are positioned adjacent to each other;
a first inductor and a second inductor each coupled to the first integrated circuit; and
a third inductor and a fourth inductor each coupled to the second integrated circuit.

11. The PCB of claim 10, wherein the first integrated circuit is coupled to the first inductor by a first corresponding terminal and the first integrated circuit is coupled to the second inductor by a second corresponding terminal; and wherein the second integrated circuit is coupled to the third inductor by a third corresponding terminal and the second integrated circuit is coupled to the fourth inductor by a fourth corresponding terminal.

12. The PCB of claim 11, wherein each of the first terminal, the second terminal, the third terminal, and the fourth terminal are positioned on a common side of each integrated circuit of the plurality of integrated circuits.

13. The PCB of claim 11, wherein a first ground terminal is coupled to the first terminal, a second ground terminal is coupled to the second terminal, a third ground terminal is coupled to the third terminal, and a fourth ground terminal is coupled to the fourth terminal.

14. The PCB of claim 13, wherein the PCB is configured to receive an input voltage routed to the first, second, third and fourth ground terminal and further routed to the first, second, third and fourth terminals and inductors, respectively, across a width of the PCB.

15. The PCB of claim 10, wherein the first inductor, the second inductor, the third inductor, and the fourth inductor are adjacent to each other on a common side of the first integrated circuit and the second integrated circuit.

16. The PCB of claim 10, wherein the first integrated circuit is coupled to a first charge pump and the second integrated circuit is coupled to a second charge pump.

17. The PCB of claim 16, wherein the first charge pump and the second charge pump each comprises one or more capacitors.

18. A printed circuit board (PCB) for power conversion, the PCB comprising:
an integrated circuit comprising buck converter circuitry; and
an inductor coupled to the integrated circuit.

19. The PCB of claim 18, wherein the inductor comprises a plurality of inductors coupled to the integrated circuit, the integrated circuit is coupled to each inductor of the plurality of inductors by a corresponding terminal, and wherein each corresponding terminal is positioned on a common side of the integrated circuit.

20. An apparatus comprising the PCB of claim 18.
